(19) United States
(12) Patent Application Publication
(10) Pub. No.: US 2026/0370115 A1
(43) Pub. Date: Nov. 19, 2026

(54) Current Sense Apparatus and Method

(71) Applicant: Reed Semiconductor Corporation, Warwick, RI (US)

(72) Inventors: Hal Chen, Short Hills, NJ (US); Jiwei Fan, Cary, NC (US); Jialun Du, Powell, OH (US)

(21) Appl. No.: 19/754,240

(22) Filed: Jul. 26, 2026

Related U.S. Application Data
(63) Continuation of application No. 19/046,494, filed on Feb. 5, 2025.
(60) Provisional application No. 63/550,502, filed on Feb. 6, 2024.

(51) Int. Cl. H02M 1/00; G01R 19/25; H02M 3/158

(52) U.S. Cl. CPC H02M 1/0009; G01R 19/2509; H02M 3/158

(57) ABSTRACT

An apparatus includes a current sense circuit configured to generate a current signal proportional to a current flowing through an inductor of a power converter when a low-side switch of the power converter is turned on, and a feedback loop configured to reconstruct an inductor current signal during an on-time of a high-side switch of the power converter based on information obtained during an on-time of the low-side switch.

### PRIORITY CLAIM AND CROSS-REFERENCE

This application is a continuation of U.S. patent application Ser. No. 19/046,494, filed on Feb. 5, 2025, entitled “Current Sense Apparatus and Method,” which claims the benefit of U.S. Provisional Application No. 63/550,502, filed on Feb. 6, 2024, entitled “Current Sense Apparatus and Method,” each application is hereby incorporated herein by reference.

### TECHNICAL FIELD

The present invention relates to a current sense apparatus and control method, and, in particular embodiments, to a current sense apparatus for a step-down power converter.

### BACKGROUND

As technologies further advance, a variety of processors such as Digital Signal Processors (DSPs), Field Programmable Gate Arrays (FPGAs), Central Processing Units (CPUs) and/or the like, have become popular. Each processor operates with a low supply voltage (e.g., sub-1V) and consumes a large amount of current. Meanwhile, the input voltage bus has stayed the same (e.g., 12 V) or increased to a higher level (e.g., 48 V) depending on different applications or design needs. In some applications, the input voltage bus may be lowered to a suitable voltage level (e.g., 1.8 V, 3.3 V, 5 V or 7.5 V).

In a high input voltage application where a low output voltage is required, a load (e.g., a processor) may be powered by a step-down power converter. The step-down power converter such as a buck converter includes two power switches connected in series between an input voltage and ground. A first power switch connected to the input voltage is referred to as a high-side switch. A second power switch connected to ground is referred to as a low-side switch. A common node of the high-side switch and the low-side switch is a switching node of the power converter. A low-side gate drive circuit and a high-side gate drive circuit are employed to control the gates of the low-side switch and the high-side switch, respectively.

The low-side switch and the high-side switch may be implemented as metal oxide semiconductor field effect transistors (MOSFET). MOSFETs are voltage-controlled devices. When a gate drive voltage is applied to the gate of a MOSFET, and the gate drive voltage is greater than the turn-on threshold of the MOSFET, a conductive channel is established between the drain and the source of the MOSFET. After the conductive channel has been established, the MOSFET is in an on state in which power flows between the drain and the source of the MOSFET. On the other hand, when the gate drive voltage applied to the gate is less than the turn-on threshold of the MOSFET, the MOSFET is turned off accordingly. The duty cycle of the buck converter is defined as the ratio of the high-side switch's on time to the total switching period. In operation, a pulse width modulation (PWM) controller continuously adjusts the duty cycle based on feedback from the output voltage to maintain a stable output despite variations in input voltage or load conditions.

As power consumption has become more important, there may be a need for accurately monitoring and/or controlling the current flowing through the power converter so as to achieve a high-efficiency, safe and reliable operation of the power converter. Current sense devices such as current sense resistors have become the preferred choice for achieving high performance (e.g., accurate current measurement information) because current sense resistors can be connected in series with the inductor of the power converter. However, as the input voltage of the power converter varies in a wide range (e.g., from 0 V to 60 V), the silicon area occupied by the current sense apparatus has become a significant issue, which presents challenges to designers of wide input range power conversion systems. It would be desirable to have a current sense apparatus for use in high power applications exhibiting good characteristics such as current sensing without using an external precision resistor, architecture simplicity, sufficiently accurate current sensing performance and low power consumption. The present disclosure addresses this need.

### SUMMARY

These and other problems are generally solved or circumvented, and technical advantages are generally achieved, by preferred embodiments of the present disclosure which provide a current sense apparatus for a step-down power converter.

In accordance with an embodiment, an apparatus comprises a PWM off time current sense circuit configured to generate a PWM off time current signal proportional to a current flowing through an inductor of a power converter when a high-side switch of the power converter is turned off and a low-side switch of the power converter is turned on, a PWM on time current rebuild circuit configured to construct an artificial inductor current signal using a voltage-controlled current source to charge a rebuild capacitor when the high-side switch of the power converter is turned on, and a feedback loop configured to adjust a current flowing through the voltage-controlled current source so as to force a saved voltage of the artificial inductor current signal to be equal to a saved voltage of the PWM off time current signal.

In accordance with another embodiment, a method comprises generating a PWM off time current signal proportional to a current flowing through an inductor of a power converter when a high-side switch of the power converter is turned off and a low-side switch of the power converter is turned on, constructing an artificial inductor current signal using a voltage-controlled current source to charge a rebuild capacitor when the high-side switch of the power converter is turned on, and adjusting a current flowing through the voltage-controlled current source so as to force a saved voltage of the artificial inductor current signal to be equal to a saved voltage of the PWM off time current signal.

In accordance with yet another embodiment, a power converter comprises a high-side switch and a low-side switch connected in series between an input voltage bus and ground, an inductor connected between a common node of the high-side switch and the low-side switch, and an output of the power converter, a controller configured to generate gate drive signals for the high-side switch and the low-side switch, respectively, and a current sense apparatus comprising a PWM off time current sense circuit configured to generate a PWM off time current signal proportional to a current flowing through an inductor of the power converter when the high-side switch of the power converter is turned off and the low-side switch of the power converter is turned on, a PWM on time current rebuild circuit configured to construct an artificial inductor current signal using a current source to charge a rebuild capacitor when the high-side switch of the power converter is turned on, and a feedback loop configured to adjust a current flowing through the voltage-controlled current source so as to force a saved voltage of the artificial inductor current signal to be equal to a saved voltage of the PWM off time current signal.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a schematic diagram of a power converter and a block diagram of a current sense apparatus for sensing a current flowing through an inductor of the power converter in accordance with various embodiments of the present disclosure;

FIG. 2 illustrates a schematic diagram of the current sense apparatus shown in FIG. 1 in accordance with various embodiments of the present disclosure;

FIG. 3 illustrates a schematic diagram of the low side current sense unit shown in FIG. 2 in accordance with various embodiments of the present disclosure;

FIG. 4 illustrates various control signals associated with the current sense apparatus shown in FIG. 2 in accordance with various embodiments of the present disclosure;

FIG. 5 illustrates various waveforms associated with the current sense apparatus shown in FIG. 2 in accordance with various embodiments of the present disclosure;

FIG. 6 illustrates a process of adjusting the artificial inductor current signal when a current flowing through the voltage-controlled current source is greater than a necessary current for reconstructing the current sense signal in accordance with various embodiments of the present disclosure;

FIG. 7 illustrates a process of adjusting the artificial inductor current signal when a current flowing through the voltage-controlled current source is less than a necessary current for reconstructing the current sense signal in accordance with various embodiments of the present disclosure;

FIG. 8 illustrates a dynamic hysteresis control feature of the current sense apparatus shown in FIG. 2 in accordance with various embodiments of the present disclosure; and

FIG. 9 illustrates a flow chart of a method for sensing the current flowing through the power converter shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to preferred embodiments in a specific context, namely a current sense apparatus for a step-down power converter. The disclosure may also be applied, however, to a variety of power conversion systems. Hereinafter, various embodiments will be explained in detail with reference to the accompanying drawings.

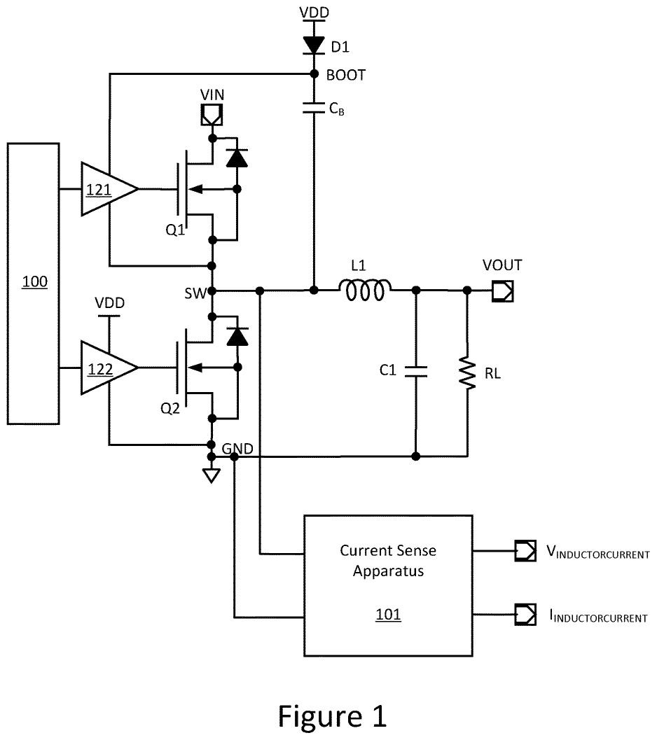

FIG. 1 illustrates a schematic diagram of a power converter and a block diagram of a current sense apparatus for sensing a current flowing through an inductor of the power converter in accordance with various embodiments of the present disclosure. The power converter is a step-down dc/dc converter. It is also known as a buck converter. As shown in FIG. 1, the power converter comprises a high-side switch Q1 and a low-side switch Q2 connected in series between an input voltage bus VIN and ground. The power converter further comprises an inductor L1 connected between a common node SW of the high-side switch Q1 and the low-side switch Q2, an output VOUT of the power converter. An output capacitor C1 is connected between the output VOUT and ground. A load RL is connected in parallel with the output capacitor C1.

The switches (e.g., Q1) shown in FIG. 1 may be implemented as n-type metal oxide semiconductor (NMOS) transistors. Alternatively, the switches may be implemented as other suitable controllable devices such as metal oxide semiconductor field effect transistor (MOSFET) devices, bipolar junction transistor (BJT) devices, super junction transistor (SJT) devices, insulated gate bipolar transistor (IGBT) devices, gallium nitride (GaN) based power devices, any combinations thereof and the like.

A controller 100 is configured to generate gate drive signals for the high-side switch Q1 and the low-side switch Q2. Furthermore, the controller 100 is configured to control the operation of the high-side switch Q1 and the low-side switch Q2 based on a plurality of operating parameters such as the output voltage and/or the current flowing through the inductor L1. In particular, the controller 100 is configured to generate a high-side PWM signal and a low-side PWM signal based on a suitable control scheme such as a valley current mode control scheme. A level shifter (not shown) and a first driver 121 are employed to receive the high-side PWM signal and generate a gate drive signal applied to the high-side switch Q1. A bias power supply VDD, a diode D1 and a bootstrap capacitor C_{B} form a bootstrap circuit configured to provide bias power for the first driver 121. A second driver 122 is employed to receive the low-side PWM signal and generate a gate drive signal applied to the low-side switch Q2. The bias power supply VDD is configured to provide bias power for the second driver 122.

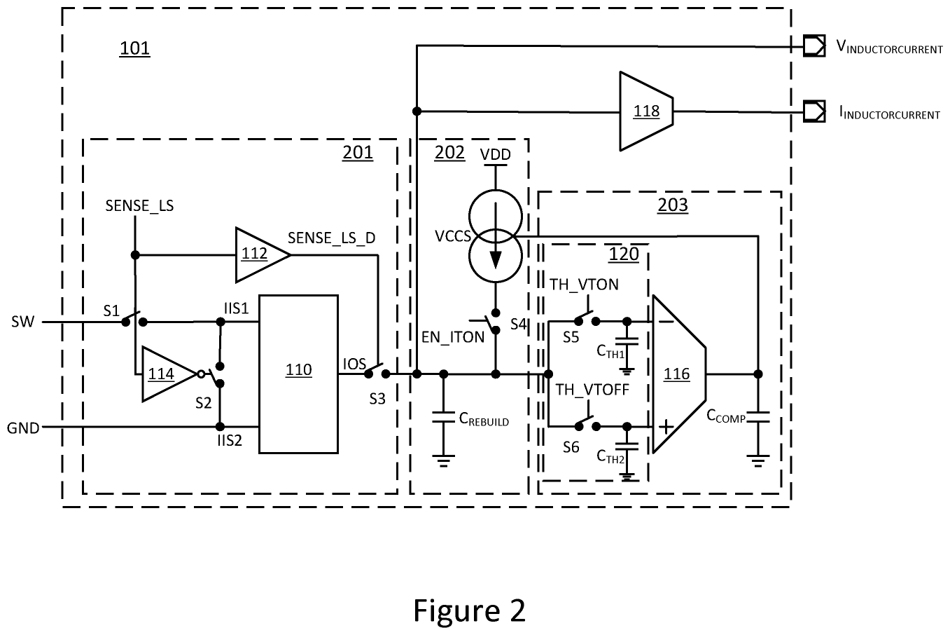

The current sense apparatus 101 is configured to sense the current flowing through the inductor L1. In some embodiments, the current sense apparatus 101 comprises a PWM off time current sense circuit, a PWM on time current rebuild circuit and a feedback loop. The detailed structure and operating principle of the current sense apparatus 101 will be described below with respect to FIG. 2.

In operation, the PWM off time current sense circuit is configured to generate a PWM off time current signal proportional to a current flowing through the inductor L1 when the high-side switch Q1 is turned off and the low-side switch Q2 is turned on. The PWM on time current rebuild circuit is configured to construct an artificial inductor current signal using a voltage-controlled current source to charge a rebuild capacitor when the high-side switch Q1 is turned on. The feedback loop is configured to adjust a current flowing through the voltage-controlled current source so as to force a saved voltage of the artificial inductor current signal to be equal to a saved voltage of the PWM off time current signal.

In operation, upon detecting that the saved voltage of the artificial inductor current signal is higher than the saved voltage of the PWM off time current signal, the voltage-controlled current source is adjusted to decrease the saved voltage of the artificial inductor current signal until the saved voltage of the artificial inductor current signal is equal to the saved voltage of the PWM off time current signal. On the other hand, upon detecting that the saved voltage of the artificial inductor current signal is lower than the saved voltage of the PWM off time current signal, the voltage-controlled current source is adjusted to increase the saved voltage of the artificial inductor current signal until the saved voltage of the artificial inductor current signal is equal to the saved voltage of the PWM off time current signal.

FIG. 2 illustrates a schematic diagram of the current sense apparatus shown in FIG. 1 in accordance with various embodiments of the present disclosure. The current sense apparatus 101 comprises a PWM off time current sense circuit 201, a PWM on time current rebuild circuit 202 and a feedback loop 203 as shown in FIG. 2.

The PWM off time current sense circuit 201 comprises a low-side switch current sense unit 110, a first switch S1, a second switch S2, a third switch S3, an inverter 114 and a delay unit 112. As shown in FIG. 2, the low-side switch current sense unit 110 has a first input IIS1 coupled to the common node SW of the high-side switch Q1 and the low-side switch Q2 through the first switch S1, a second input IIS2 connected to ground, and an output IOS configured to generate a PWM off time current signal.

As shown in FIG. 2, the third switch is connected to the output of the low-side switch current sense unit 110. A low-side current sense control signal SENSE_LS is configured to control the first switch S1 directly, and control the second switch S2 through the inverter 114. The low-side current sense control signal SENSE_LS is also configured to control the third switch S3 through the delay unit 112. The delay unit 112 is configured to add a predetermined delay into the low-side current sense control signal SENSE_LS. The delay unit 112 generates a delayed rising edge signal SENSE_LS_D. In other words, there is a predetermined delay between the rising edge of SENSE_LS and the rising edge of SENSE_LS_D. As shown in FIG. 2, the PWM off time current signal generated by the low-side switch current sense unit 110 is fed into a rebuild capacitor C_{REBUILD} through the third switch S3.

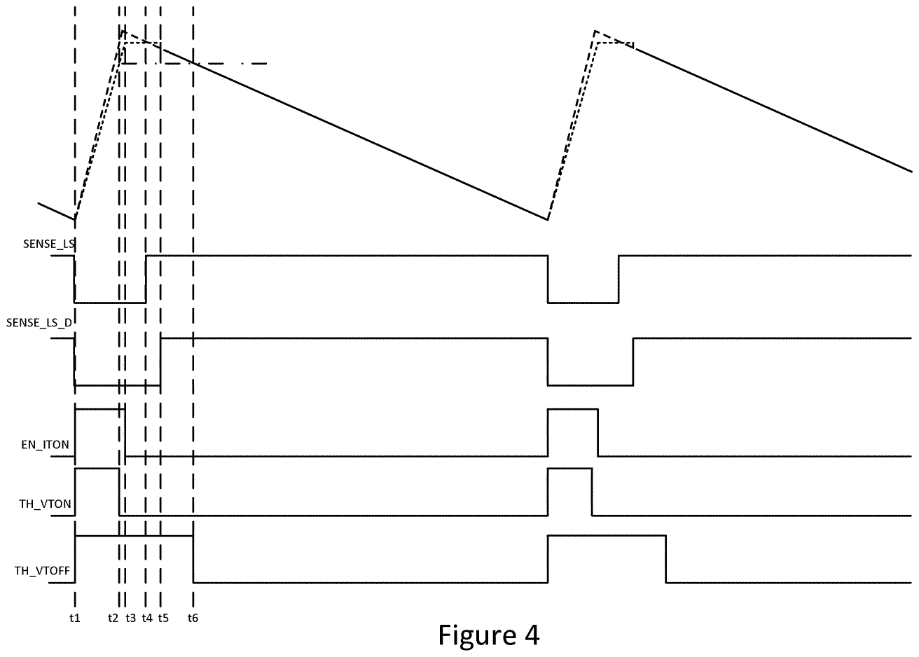

In operation, the PWM off time current sense circuit 201 is configured to generate the PWM off time current signal proportional to a current flowing through the inductor L1 when the high-side switch Q1 of the power converter is turned off and the low-side switch Q2 of the power converter is turned on. The detailed operation principle of the PWM off time current sense circuit 201 will be discussed below with respect to FIG. 4.

The PWM on time current rebuild circuit 202 comprises a voltage-controlled current source VCCS, a rebuild capacitor C_{REBUILD} and a fourth switch S4. The voltage-controlled current source VCCS, the fourth switch S4 and the rebuild capacitor C_{REBUILD} are connected in series between a bias voltage source VDD and ground. The fourth switch S4 is controlled by an enable signal EN_ITON. The enable signal EN_ITON is configured such that the fourth switch S4 is turned on when the high-side switch Q1 is turned on.

In operation, the PWM on time current rebuild circuit 202 is configured to construct an artificial inductor current signal using the voltage-controlled current source VCCS to charge the rebuild capacitor C_{REBUILD} when the high-side switch Q1 of the power converter is turned on. The detailed operation principle of the PWM on time current rebuild circuit 202 will be discussed below with respect to FIG. 4.

The feedback loop comprises 203 a track-and-hold circuit 120, a first transconductance amplifier 116 and a compensation capacitor C_{COMP}. An input of the track-and-hold circuit 120 is connected to both the PWM off time current sense circuit 201 and the PWM on time current rebuild circuit 202. Two inputs of the first transconductance amplifier 116 are connected to two outputs of the track-and-hold circuit 120, respectively. The compensation capacitor C_{COMP} is connected to an output of the first transconductance amplifier 116.

As shown in FIG. 2, the track-and-hold circuit 120 comprises a fifth switch S5, a first hold capacitor C_{TH1}, a sixth switch S6 and a second hold capacitor C_{TH2}. The fifth switch S5 and the first hold capacitor C_{TH1} are connected in series between the input of the track-and-hold circuit 120 and ground. A common node of the fifth switch S5 and the first hold capacitor C_{TH1} is connected to a first input of the first transconductance amplifier 116. The sixth switch S6 and the second hold capacitor C_{TH2} are connected in series between the input of the track-and-hold circuit 120 and ground. A common node of the sixth switch S6 and the second hold capacitor C_{TH2} is connected to a second input of the first transconductance amplifier 116.

In operation, the fifth switch S5 is controlled by a first control signal TH_VTON. The first control signal TH_VTON is configured such that a saved voltage of the artificial inductor current signal is held on the first hold capacitor C_{TH1}. The saved voltage of the artificial inductor current signal will be discussed below with respect to FIG. 4. The sixth switch S6 is controlled by a second control signal TH_VTOFF. The second control signal TH_VTOFF is configured such that a saved voltage of the PWM off time current signal is held on the second hold capacitor C_{TH2}. The saved voltage of the PWM off time current signal will be discussed below with respect to FIG. 4.

In operation, the feedback loop 203 is configured to adjust a current flowing through the voltage-controlled current source VCCS so as to make the saved voltage of the artificial inductor current signal equal to the saved voltage of the PWM off time current signal. Once the saved voltage of the artificial inductor current signal is equal to the saved voltage of the PWM off time current signal, the artificial inductor current signal is of a shape similar to that of the current flowing through the high-side switch Q1.

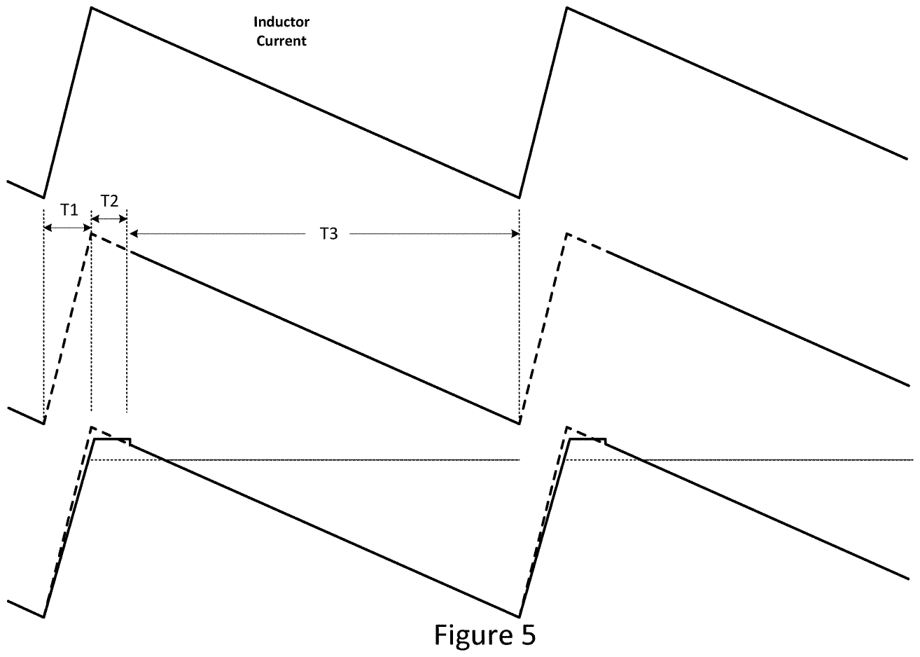

In some embodiments, the PWM off time current sense circuit 201, the PWM on time current rebuild circuit 202 and the feedback loop 203 are configured to generate an inductor current detection signal V_{INDUCTORCURRENT}. The inductor current detection signal V_{INDUCTORCURRENT} includes three portions. A first portion of the inductor current detection signal is formed by sensing a current flowing through the low-side switch when the low-side switch is turned on. A second portion of the inductor current detection signal is based on the artificial inductor current signal when the high-side switch is turned on. A third portion of the inductor current detection signal is formed by holding a voltage on a rebuild capacitor during a blanking time and a settling time at a beginning of an on-time of the low-side switch. The third portion of the inductor current detection signal is of a flat top. The inductor current detection signal having three portions will be discussed in further detail below with respect to FIG. 5.

As shown in FIG. 2, the inductor current detection signal V_{INDUCTORCURRENT} is directly tapped at the upper terminal of the rebuild capacitor C_{REBUILD.} A second transconductance amplifier 118 is employed to convert the inductor current detection signal V_{INDUCTORCURRENT} into a corresponding current signal I_{INDUCTORCURRENT.}

It should be noted that the single-ended current sense apparatus shown in FIG. 2 can be designed in a fully-differential form. More particularly, the low-side switch current sense unit 110 can be implemented as a fully-differential amplifier. The two outputs of the fully-differential amplifier are fed into two rebuild capacitors, two voltage-controlled current sources, two track-and-hold circuits and two transconductance amplifiers. In other words, there are two closely related symmetrical PWM on time current rebuild circuits in a current sense apparatus designed in a fully-differential form.

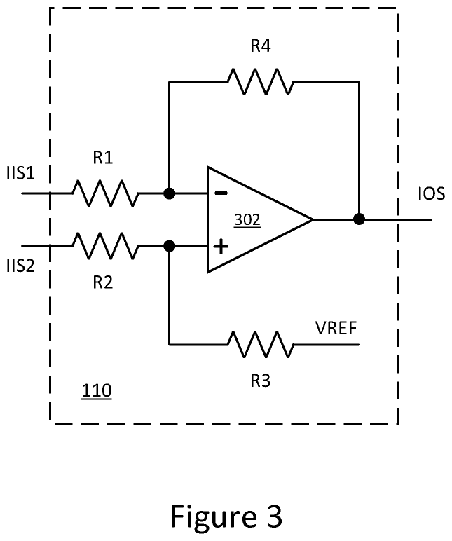

FIG. 3 illustrates a schematic diagram of the low side current sense unit shown in FIG. 2 in accordance with various embodiments of the present disclosure. In some embodiments, the low-side switch current sense unit 110 is implemented as a differential to single-ended amplifier. As shown in FIG. 3, the differential to single-ended amplifier comprises an amplifier 302, a first resistor R1, a second resistor R2, a third resistor R3 and a fourth resistor R4.

The first resistor R1 is connected between the first input IIS1 and an inverting input of the amplifier 302. The second resistor R2 is connected between the second input IIS2 and a non-inverting input of the amplifier 302. The third resistor R3 is connected between the non-inverting input of the amplifier 302 and a predetermined reference VREF. The fourth resistor R4 is connected between the inverting input of the amplifier 302 and the output IOS of the amplifier 302.

FIG. 4 illustrates various control signals associated with the current sense apparatus shown in FIG. 2 in accordance with various embodiments of the present disclosure. The horizontal axis of FIG. 4 represents intervals of time. There are six rows in FIG. 4. The first row represents the current flowing through the inductor and the inductor current detection signal. The second row represents the low-side current sense control signal SENSE_LS. The third row represents a delayed rising edge signal SENSE_LS_D. The fourth row represents the enable signal EN_ITON. The fifth row represents the first control signal TH_VTON. The sixth row represents the second control signal TH_VTOFF.

At t1, the high-side switch Q1 is turned on. The current (dashed line) flowing through the inductor increases in a linear manner from t1 to t3. Both SENSE_LS and SENSE_LS_D change from a logic high level to a logic low level. As a result of this logic change, S1 is turned off, S2 is turned on, and S3 is turned off. Referring back to FIG. 2, the on/off configuration of S1, S2 and S3 indicates the PWM off time current sense circuit 201 is prevented from having an impact on the rebuild capacitor C_{REBUILD}.

At t1, EN_ITON, TH_VTON and TH_VTOFF change from a logic low level to a logic high level. In response to the logic change, switches S4, S5 and S6 are turned on. Referring back to FIG. 2, once S4 is turned on, the PWM on time current rebuild circuit 202 is enabled. The voltage-controlled current source VCCS charges the rebuild capacitor C_{REBUILD} to generate the artificial inductor current signal. The artificial inductor current signal (dotted line) increases in a linear manner from t1 to t3. Once S5 is turned on at t1, the first hold capacitor C_{TH1} is connected in parallel with the rebuild capacitor C_{REBUILD}. Likewise, once S6 is turned on at t1, the second hold capacitor C_{TH2} is connected in parallel with the rebuild capacitor C_{REBUILD}.

At t2, TH_VTON changes from a logic high level to a logic low level. In response to this logic change, the voltage of the artificial inductor current signal at t2 is stored on the first hold capacitor C_{TH1}. The voltage of the artificial inductor current signal at t2 is alternatively referred to as a saved voltage of the artificial inductor current signal.

At t3, the current flowing through the inductor reaches its peak. EN_ITON changes from a logic high level to a logic low level. In response to this logic change, S4 is turned off. The voltage-controlled current source VCCS stops charging the rebuild capacitor C_{REBUILD}. As shown in FIG. 4, the logic transition of TH_VTON is slightly earlier than the logic transition of EN_ITON. This predetermined time gap between the falling edges of TH_VTON and EN_ITON prevents the noise signal from having an impact on the saved voltage of the artificial inductor current signal.

At t3, the low-side switch Q2 is turned on. The current (dashed line) flowing through the inductor decrease in a linear manner from t3 to the end of this switching cycle. From t3 to t4, a time period is usually referred to as a blanking time in which a large amount of ringing and noise can appear on the common switching node SW and the sensing of the low-side switch current becomes impossible. As a result, the low-side switch current sense unit 110 will not sense the current flowing through the low-side switch Q2 during this blanking time. At t4, SENSE_LS changes from a logic low level to a logic high level. In response to the logic change of SENSE_LS, S1 is turned on, and S2 is turned off. The low-side switch current sense unit 110 is enabled to sense the current flowing through the low-side switch Q2. After an amplifier settling time, at t5, SENSE_LS_D changes from a logic low level to a logic high level. In response to this logic change, S3 is turned on. The PWM off time current signal is applied to the rebuild capacitor C_{REBUILD}. During the blanking time plus the settling time from t3 to t5, EN_ITON is of a logic low level and S4 is turned off. The voltage-controlled current source VCCS cannot charge the rebuild capacitor C_{REBUILD}. In other words, from t3 to t5, the voltage across the rebuild capacitor C_{REBUILD} remains the same. The corresponding inductor current detection signal has a flat top shape from t3 to t5 as shown in FIG. 4.

After an additional amplifier settling time, at t6, TH_VTOFF changes from a logic high level to a logic low level. In response to this logic change, the voltage of the PWM off time current signal at t6 is stored on the second hold capacitor C_{TH2}. The voltage of the PWM off time current signal at t6 is alternatively referred to as a saved voltage of the PWM off time current signal.

In operation, the track-and-hold circuit 120, the first transconductance amplifier 116, the compensation capacitor C_{COMP} and the voltage-controlled current source VCCS are configured to operate in a negative feedback fashion such that the saved voltage of the artificial inductor current signal is forced to be approximately equal to the saved voltage of the PWM off time current signal.

In summary, the current sense apparatus depicted in FIG. 2 generates a complete inductor current detection signal by combining three signal components. The first component is obtained by sensing the current flowing through the low-side switch Q2 during the PWM off time, excluding the blanking period, when the low-side switch Q2 is turned on. The second component is created by charging the rebuild capacitor with a voltage-controlled current source, forming an artificial segment of the inductor current signal during the PWM on time. The third component is established by maintaining the voltage of the rebuild capacitor during the blanking period of the PWM off time.

FIG. 5 illustrates various waveforms associated with the current sense apparatus shown in FIG. 2 in accordance with various embodiments of the present disclosure. The horizontal axis of FIG. 5 represents intervals of time. There are three waveforms in FIG. 5. The top waveform shows the current flowing through the inductor L1. The middle waveform shows, in one switching cycle, the inductor current detection signal can be divided into three time periods. In a first time period T1, the inductor current flows through the high-side switch Q1. The inductor current detection signal is based on the artificial inductor current signal generated by the voltage-controlled current source VCCS charging a rebuild capacitor. In a second time period T2, the inductor current flows through the low-side switch Q2. In this time period, ringing and noise prevent the proper detection of the inductor current flowing through the low-side switch Q2. This is a blanking time period. The voltage across the rebuild capacitor C_{REBUILD} remains the same. The corresponding inductor current detection signal has a flat top shape during the blanking time period. In a third time period T3, the inductor current flows through the low-side switch Q2. In this time period, the inductor current flowing through the low-side switch Q2 can be properly sensed and detected. The bottom waveform shows the complete inductor current detection signal (the solid line portions in T1 and T2) overlaid on the ideal inductor current signal (the dashed line portions in T1 and T2).

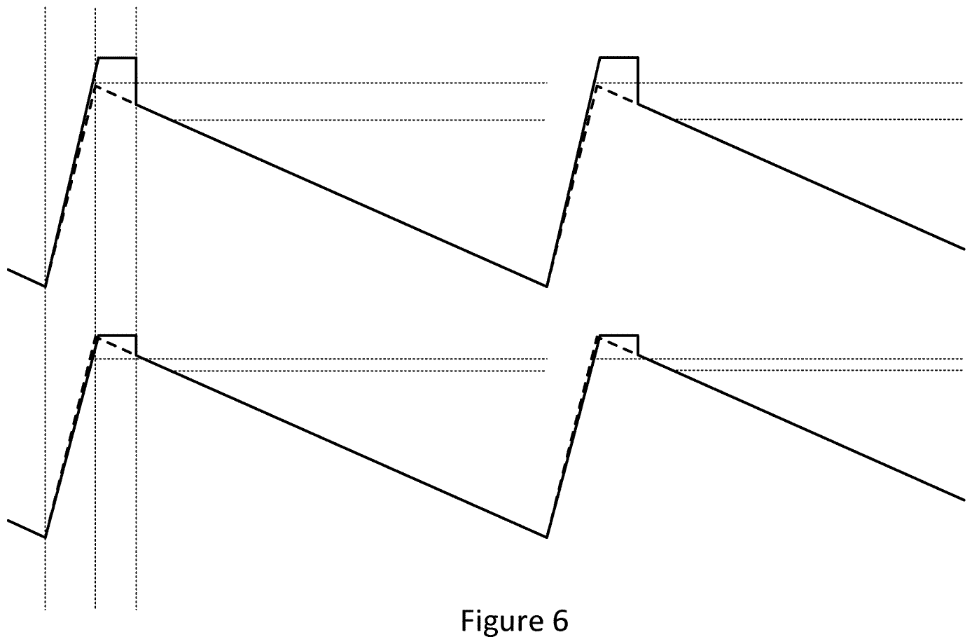

FIG. 6 illustrates a process of adjusting the artificial inductor current signal when a current flowing through the voltage-controlled current source is greater than a necessary current for reconstructing the current sense signal in accordance with various embodiments of the present disclosure. The horizontal axis of FIG. 6 represents intervals of time. There are two waveforms in FIG. 6. The top waveform shows the saved voltage of the artificial inductor current signal (the upper horizontal dashed line) is much higher than the saved voltage of the PWM off time current signal (the lower horizontal dashed line). The feedback loop 203 shown in FIG. 2 detects this difference and adjusts the voltage-controlled current source VCCS accordingly to decrease the saved voltage of the artificial inductor current signal. As indicated by the bottom waveform, the difference between the saved voltage of the artificial inductor current signal and the saved voltage of the PWM off time current signal is reduced. It should be noted that in the steady state operation, the saved voltage of the artificial inductor current signal is approximately equal to the saved voltage of the PWM off time current signal as shown in FIG. 6.

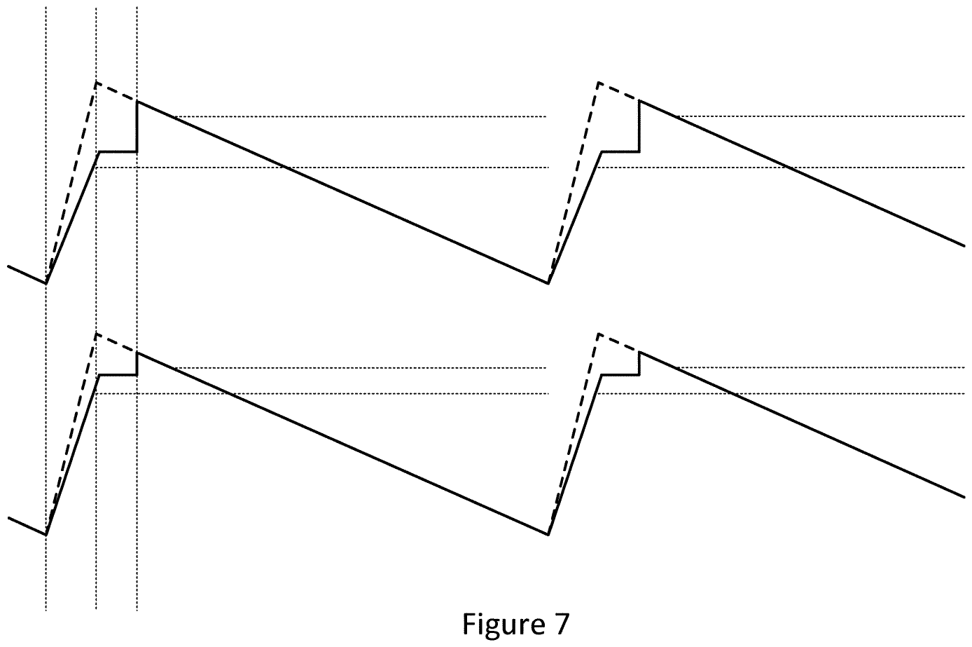

FIG. 7 illustrates a process of adjusting the artificial inductor current signal when a current flowing through the voltage-controlled current source is less than a necessary current for reconstructing the current sense signal in accordance with various embodiments of the present disclosure. The horizontal axis of FIG. 7 represents intervals of time. There are two waveforms in FIG. 7. The top waveform shows the saved voltage of the artificial inductor current signal (the lower horizontal dashed line) is much lower than the saved voltage of the PWM off time current signal (the upper horizontal dashed line). The feedback loop 203 shown in FIG. 2 detects this difference and adjusts the voltage-controlled current source VCCS accordingly to increase the saved voltage of the artificial inductor current signal. As indicated by the bottom waveform, the difference between the saved voltage of the artificial inductor current signal and the saved voltage of the PWM off time current signal is reduced. It should be noted that in the steady state operation, the saved voltage of the artificial inductor current signal is approximately equal to the saved voltage of the PWM off time current signal as shown in FIG. 7.

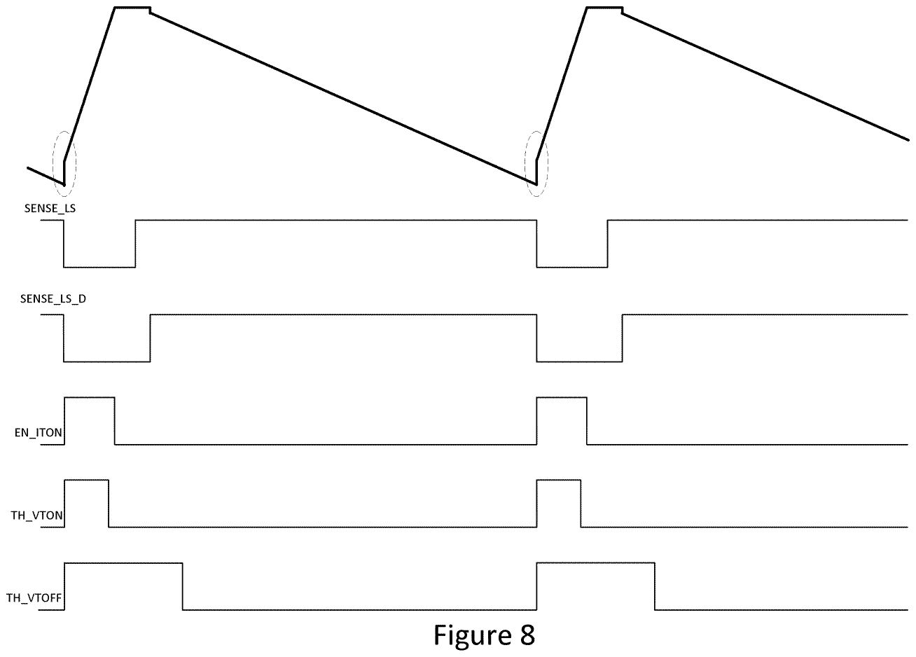

FIG. 8 illustrates a dynamic hysteresis control feature of the current sense apparatus shown in FIG. 2 in accordance with various embodiments of the present disclosure. The horizontal axis of FIG. 8 represents intervals of time. There are six rows in FIG. 8. The first row represents the inductor current detection signal. The second row represents the low-side current sense control signal SENSE_LS. The third row represents a delayed rising edge signal SENSE_LS_D. The fourth row represents the enable signal EN_ITON. The fifth row represents the first control signal TH_VTON. The sixth row represents the second control signal TH_VTOFF.

The various control signals shown in FIG. 8 are similar to those shown in FIG. 4, and hence are not discussed herein again. The inductor current detection signal in the dashed oval includes a voltage jump. The voltage jump occurs at a beginning of the artificial inductor current signal as a result of connecting the first hold capacitor C_{TH1} and the second hold capacitor C_{TH2} in parallel with the rebuild capacitor C_{REBUILD}. In a valley current mode control scheme, this voltage jump improves the noise immunity of the control loop and eliminates incorrect triggers caused by noisy signals, thereby achieving hysteresis control.

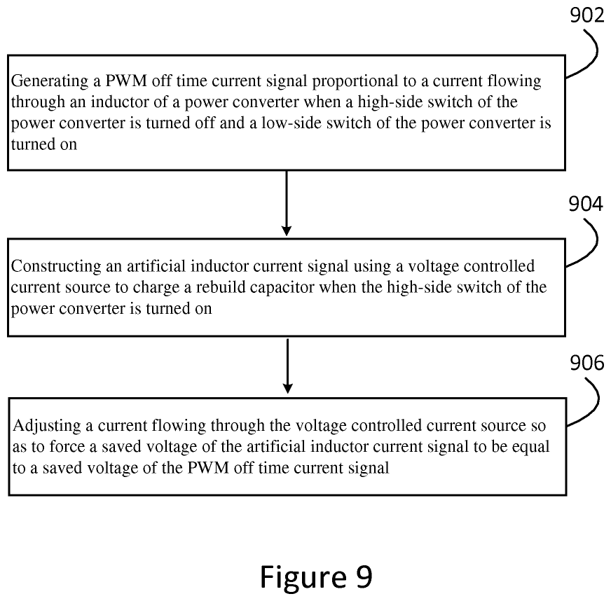

FIG. 9 illustrates a flow chart of a method for sensing the current flowing through the power converter shown in FIG. 1 in accordance with various embodiments of the present disclosure. This flowchart shown in FIG. 9 is merely an example, which should not unduly limit the scope of the claims. One of ordinary skill in the art would recognize many variations, alternatives, and modifications. For example, various steps illustrated in FIG. 9 may be added, removed, replaced, rearranged and repeated.

At step 902, a PWM off time current signal proportional to a current flowing through an inductor of a power converter is generated when a high-side switch of the power converter is turned off and a low-side switch of the power converter is turned on.

At step 904, an artificial inductor current signal is constructed using a voltage-controlled current source to charge a rebuild capacitor when the high-side switch of the power converter is turned on.

At step 906, a current flowing through the voltage-controlled current source is adjusted so as to force a saved voltage of the artificial inductor current signal to be equal to a saved voltage of the PWM off time current signal.

The method further comprises configuring the voltage-controlled current source to be connected to the rebuild capacitor through a controllable switch, and in response to an enable signal, configuring the controllable switch to be turned on when the high-side switch is turned on.

The method further comprises configuring the PWM off time current sense circuit, the PWM on time current rebuild circuit and the feedback loop to generate an inductor current detection signal including three portions, and wherein a first portion of the inductor current detection signal is formed by sensing a current flowing through the low-side switch when the low-side switch is turned on, a second portion of the inductor current detection signal is reconstructed by the artificial inductor current signal when the high-side switch is turned on, and a third portion of the inductor current detection signal is formed by holding a voltage on the rebuild capacitor during a blanking time and a settling time at a beginning of an on-time of the low-side switch, and wherein the third portion of the inductor current detection signal is of a flat top.

The method further comprises upon detecting that the saved voltage of the artificial inductor current signal is higher than the saved voltage of the PWM off time current signal, adjusting the voltage-controlled current source to decrease the saved voltage of the artificial inductor current signal until the saved voltage of the artificial inductor current signal is equal to the saved voltage of the PWM off time current signal.

The method further comprises upon detecting that the saved voltage of the artificial inductor current signal is lower than the saved voltage of the PWM off time current signal, adjusting the voltage-controlled current source to increase the saved voltage of the artificial inductor current signal until the saved voltage of the artificial inductor current signal is equal to the saved voltage of the PWM off time current signal.

In some embodiments, the power converter comprises the high-side switch and the low-side switch connected in series between an input voltage bus and ground, and an inductor connected between a common node of the high-side switch and the low-side switch, and an output of the power converter.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus comprising:
a current sense circuit configured to generate a current signal proportional to a current flowing through an inductor of a power converter when a low-side switch of the power converter is turned on; and
a feedback loop configured to reconstruct an inductor current signal during an on-time of a high-side switch of the power converter based on information obtained during an on-time of the low-side switch.

2. The apparatus of claim 1, wherein an artificial inductor current signal is generated by reconstructing the inductor current signal during the on-time of the high-side switch, and wherein the current signal and the artificial inductor current signal collectively form an inductor current detection signal comprising:
a first portion formed by sensing a current flowing through the low-side switch when the low-side switch is turned on;
a second portion formed by the artificial inductor current signal when the high-side switch is turned on; and
a third portion having a substantially flat top, formed by holding a level of the artificial inductor current signal during a blanking time and a settling time at a beginning of an on-time of the low-side switch.

3. The apparatus of claim 1, wherein the current sense circuit comprises a low-side switch current sense unit, and wherein:
the low-side switch current sense unit is implemented as a differential to single-ended amplifier comprising an amplifier and a plurality of resistors coupled to the amplifier, and wherein the plurality of resistors comprises:
a first resistor coupled between a first input of the low-side switch current sense unit and an inverting input of the amplifier;
a second resistor coupled between a second input of the low-side switch current sense unit and a non-inverting input of the amplifier;
a third resistor coupled between the non-inverting input of the amplifier and a reference voltage; and
a fourth resistor coupled between the inverting input of the amplifier and an output of the amplifier.

4. The apparatus of claim 1, further comprising:
a PWM on time current rebuild circuit comprising a voltage-controlled current source and a rebuild capacitor, wherein the voltage-controlled current source is configured to charge the rebuild capacitor to generate an artificial inductor current signal, and wherein the feedback loop is configured to adjust a current flowing through the voltage-controlled current source so as to force a saved voltage of the artificial inductor current signal to be equal to a saved voltage of the current signal generated by the current sense circuit.

5. The apparatus of claim 4, further comprising:
a transconductance amplifier coupled to the rebuild capacitor and configured to convert a voltage of the rebuild capacitor into a corresponding current signal.

6. The apparatus of claim 4, wherein:
the current sense circuit comprises a low-side switch current sense unit, a switch and a delay unit, wherein:
the switch is coupled between an output of the low-side switch current sense unit and the rebuild capacitor; and
the delay unit is configured to generate a delayed control signal by adding a predetermined delay to a control signal used to enable the low-side switch current sense unit, and wherein the switch is controlled by the delayed control signal such that the current signal is fed into the rebuild capacitor after an amplifier settling time following enablement of the low-side switch current sense unit has elapsed.

7. The apparatus of claim 4, wherein:
the power converter is configured to operate according to a valley current mode control scheme;
the feedback loop further comprises a first hold capacitor and a second hold capacitor; and
connecting the first hold capacitor and the second hold capacitor in parallel with the rebuild capacitor at a beginning of an on-time of the high-side switch causes a voltage jump at a beginning of the artificial inductor current signal, and wherein the voltage jump provides hysteresis to the valley current mode control scheme by preventing an incorrect trigger of the valley current mode control scheme caused by a noise signal.

8. The apparatus of claim 4, wherein:
the current sense circuit comprises a low-side switch current sense unit, a first switch, a second switch and a third switch; and
during an on-time of the high-side switch, the first switch is turned off, the second switch is turned on to couple a first input and a second input of the low-side switch current sense unit together, and the third switch is turned off, such that the current sense circuit is prevented from affecting a voltage on the rebuild capacitor.

9. A method comprising:
generating, using a PWM off time current sense circuit comprising a low-side switch current sense unit, a PWM off time current signal proportional to a current flowing through an inductor of a power converter, when a low-side switch of the power converter is turned on; and
forcing, using a feedback loop, a saved voltage of an artificial inductor current signal, generated during an on-time of a high-side switch of the power converter, to be equal to a saved voltage of the PWM off time current signal generated by the low-side switch current sense unit during an on-time of the low-side switch.

10. The method of claim 9, further comprising:
constructing the artificial inductor current signal using a voltage-controlled current source to charge a rebuild capacitor when the high-side switch of the power converter is turned on, wherein forcing the saved voltage of the artificial inductor current signal to be equal to the saved voltage of the PWM off time current signal comprises adjusting a current flowing through the voltage-controlled current source.

11. The method of claim 10, further comprising:
converting a voltage of the rebuild capacitor into a corresponding current signal using a transconductance amplifier.

12. The method of claim 10, wherein:
the low-side switch current sense unit is implemented as a differential to single-ended amplifier comprising an amplifier and a plurality of resistors coupled to the amplifier, and wherein the plurality of resistors comprises:
a first resistor coupled between a first input of the low-side switch current sense unit and an inverting input of the amplifier;
a second resistor coupled between a second input of the low-side switch current sense unit and a non-inverting input of the amplifier;
a third resistor coupled between the non-inverting input of the amplifier and a reference voltage; and
a fourth resistor coupled between the inverting input of the amplifier and an output of the amplifier.

13. The method of claim 10, further comprising:
generating a delayed control signal by adding a predetermined delay to a control signal used to enable the low-side switch current sense unit; and
controlling a switch, coupled between an output of the low-side switch current sense unit and the rebuild capacitor, using the delayed control signal, such that the PWM off time current signal is fed into the rebuild capacitor only after an amplifier settling time following enablement of the low-side switch current sense unit has elapsed.

14. The method of claim 10, further comprising:
operating the power converter according to a valley current mode control scheme; and
connecting a first hold capacitor and a second hold capacitor in parallel with the rebuild capacitor at a beginning of an on-time of the high-side switch to cause a voltage jump at a beginning of the artificial inductor current signal, wherein the voltage jump provides hysteresis to the valley current mode control scheme by preventing an incorrect trigger of the valley current mode control scheme caused by a noise signal.

15. The method of claim 10, further comprising:
turning off a first switch, turning on a second switch to couple a first input and a second input of the low-side switch current sense unit together, and turning off a third switch, during an on-time of the high-side switch, such that the PWM off time current sense circuit is prevented from affecting a voltage on the rebuild capacitor.

16. A power converter comprising:
a high-side switch and a low-side switch connected in series between an input voltage bus and ground;
an inductor connected between a common node of the high-side switch and the low-side switch, and an output of the power converter;
a controller configured to generate gate drive signals for the high-side switch and the low-side switch, respectively; and
a current sense apparatus configured to sense a current flowing through the inductor, wherein the current sense apparatus comprises:
a PWM off time current sense circuit comprising a low-side switch current sense unit, wherein the PWM off time current sense circuit is configured to generate a PWM off time current signal proportional to the current flowing through the inductor when the low-side switch is turned on; and
a feedback loop configured to reconstruct an inductor current signal during an on-time of the high-side switch of the power converter based on information obtained during an on-time of the low-side switch.

17. The power converter of claim 16, wherein:
the current sense apparatus further comprises a PWM on time current rebuild circuit comprising a voltage-controlled current source and a rebuild capacitor, wherein the voltage-controlled current source is configured to charge the rebuild capacitor to generate an artificial inductor current signal, and wherein the feedback loop is configured to adjust a current flowing through the voltage-controlled current source so as to force a saved voltage of the artificial inductor current signal to be equal to a saved voltage of the PWM off time current signal.

18. The power converter of claim 17, wherein:
the low-side switch current sense unit is implemented as a differential to single-ended amplifier comprising an amplifier and a plurality of resistors coupled to the amplifier, and wherein the plurality of resistors comprises:
a first resistor coupled between a first input of the low-side switch current sense unit and an inverting input of the amplifier;
a second resistor coupled between a second input of the low-side switch current sense unit and a non-inverting input of the amplifier;
a third resistor coupled between the non-inverting input of the amplifier and a reference voltage; and
a fourth resistor coupled between the inverting input of the amplifier and an output of the amplifier.

19. The power converter of claim 17, wherein:
the current sense apparatus further comprises a transconductance amplifier coupled to the rebuild capacitor and configured to convert a voltage of the rebuild capacitor into a corresponding current signal.

20. The power converter of claim 17, wherein:
the controller is configured to generate the gate drive signals according to a valley current mode control scheme;
the feedback loop further comprises a first hold capacitor and a second hold capacitor; and
connecting the first hold capacitor and the second hold capacitor in parallel with the rebuild capacitor at a beginning of the on-time of the high-side switch causes a voltage jump at a beginning of the artificial inductor current signal, wherein the voltage jump provides hysteresis to the valley current mode control scheme by preventing an incorrect trigger of the valley current mode control scheme caused by a noise signal.
